(19) United States
(12) Patent Application Publication
(10) Pub. No.: US 2011/0090106 A1
(43) Pub. Date: Apr. 21, 2011

(54) DIGITAL-TO-ANALOG CONVERTER WITH MULTI-SEGMENTED CONVERSION

(76) Inventors: Shu-Chuan Huang, Taipei County (TW); Chun-Hsien Chou, Taipei County (TW); Chih-Cheng Wang, Taipei City (TW); Shih-Meng Chang, Taipei County (TW); Chi-Neng Mo, Taoyuan County (TW)

(21) Appl. No.: 12/626,616

(22) Filed: Nov. 26, 2009

(30) Foreign Application Priority Data
Oct. 15, 2009 (TW) 098134929

(51) Int. Cl. H03M 1/66

(52) U.S. Cl. 341/145

(57) ABSTRACT

A 12-bit DAC includes a resistor string, three 16-to-1 selectors and an adder. The 12-bit DAC receives a 12-bit digital input data and provides a corresponding analog output voltage with 3-segmented conversion. The resistor string includes a plurality of voltage-dividing units for providing a plurality of reference voltages corresponding to each segment of conversion. After receiving the plurality of reference voltages generated by the resistor string, the three 16-to-1 selectors output 3 reference voltages corresponding to the three segments of conversion according to the 4 most significant bits, 4 least significant bits and the other 4 bits in the 12-bit digital input data, respectively. The adder can then generate the corresponding output analog voltage by summing the 3 reference voltages.

### BACKGROUND OF THE INVENTION

1. Field of the Invention

The present invention is related to a digital-to-analog converter, and more particularly, to a small-size digital-to-analog converter which provides multi-segmented conversion.

2. Description of the Prior Art

Liquid crystal display (LCD) devices, characterized in thin appearance, low power consumption and low radiation, have been widely used in various electronic products, such as computer systems, mobile phones or personal digital assistants (PDAs). In a typical LCD device, source drivers and gate drivers are used for driving the pixels of the panel. A source driver normally includes a shift register, an input register, a data latch, a digital-to-analog converter (DAC) and an output buffer. The DAC can convert a digital input voltage into an analog output voltage, which generally has a linear relationship with the digital input voltage. However, since the relationship between the brightness and the applied voltage of an LCD device is not linear, the DAC of a source driver normally uses a resistor string for providing Gamma voltage compensation.

Reference is made to FIG. 1 for a diagram illustrating a prior art N-bit DAC 100. The DAC 10, including a resistor string 110 and a 2^{N}-to-1 selector 120, can provide an analog output voltage V_{OUT} according to an N-bit digit input data [D₀;D_{N-1}]. The resistor string 100, coupled between a positive bias voltage V_{REFH} and a negative bias voltage V_{REFL}, can provide 2^{N} reference voltages V₁˜V₂_{^{N}} by voltage-dividing the voltage difference ΔV_{REF} (ΔV_{REF}=V_{REFH}−V_{REFL}) using 2^{N} voltage-dividing units R₁˜R₂_{^{N}}. The 2^{N}-to-1 selector 120 is coupled to two adjacent resistors of the resistor string 110 for receiving the 2^{N} reference voltages V₁˜V₂_{^{N}}, one of which is then outputted as the analog output voltage V_{OUT} according to the N-bit digit input data [D₀;D_{N-1}].

In the prior art, the size of the N-bit DAC 100 largely increases with resolution. With 1-bit increment in panel resolution, the size of the N-bit DAC 100 approximately doubles. For example, assuming the size of a prior art 10-bit DAC 100 is equal to A, then the size of a prior art 12-bit DAC 100 is approximately equal to 4A. Therefore, the prior art N-bit DAC 100 becomes bulky in order to achieve high resolution.

### SUMMARY OF THE INVENTION

The present invention provides a digital-to-analog converter (DAC) which receives an N-bit digital input data and provides a corresponding analog voltage with multi-segmented conversion. The DAC comprises resistor string, first through third multiple-to-one selectors and an adder. The resistor string includes 2^{A} first voltage-dividing units coupled in series for providing 2^{A} reference voltages respectively corresponding to A most significant bits of the N-bit digital input data. A first voltage-dividing unit among the 2^{A} first voltage-dividing units comprises 2^{B} second voltage-dividing units coupled in series for providing 2^{B} reference voltages respectively corresponding to B most significant bits of the N-bit digital input data after the A most significant bits of the N-bit digital input data. A second voltage-dividing unit among the 2^{B} second voltage-dividing units comprises 2^{C} third voltage-dividing units coupled in series for providing 2^{C} reference voltages respectively corresponding to C most significant bits of the N-bit digital input data after the (A+B) most significant bits of the N-bit digital input data, wherein N, A, B and C are positive integers and a sum of A, B and C does not exceed N. The first multiple-to-one selector receives the 2^{A} reference voltages outputted by the first voltage-dividing unit and outputs one of the received 2^{A} reference voltages according to an A-bit digital signal. The second multiple-to-one selector receives the 2^{B} reference voltages outputted by the second voltage-dividing unit and outputs one of the received 2^{B} reference voltages according to a B-bit digital signal. The third multiple-to-one selector receives the 2^{C} reference voltages outputted by the third voltage-dividing unit and outputs one of the received 2^{C} reference voltages according to a C-bit digital signal. The adder generates the analog voltage by summing the reference voltages outputted by the first, second and third multiple-to-one selectors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a prior art N-bit DAC.

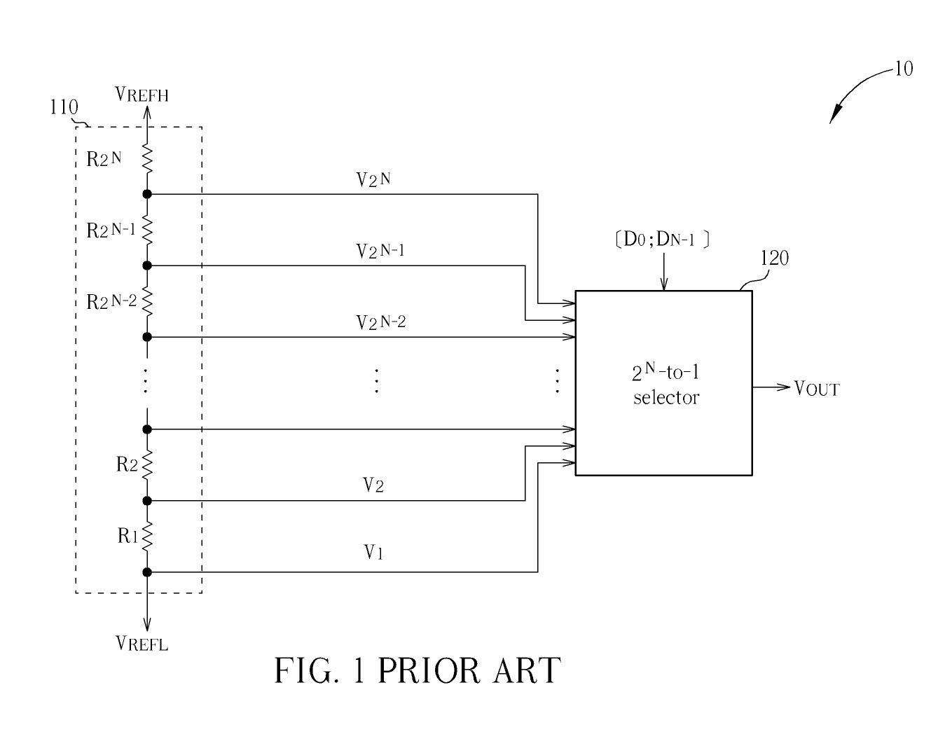

FIG. 2 is a diagram illustrating an N-bit DAC according to the present invention.

FIG. 3 is a diagram illustrating a DAC according to an embodiment of the present invention.

FIG. 4 is a table illustrating the difference between the prior art and the present invention.

### DETAILED DESCRIPTION

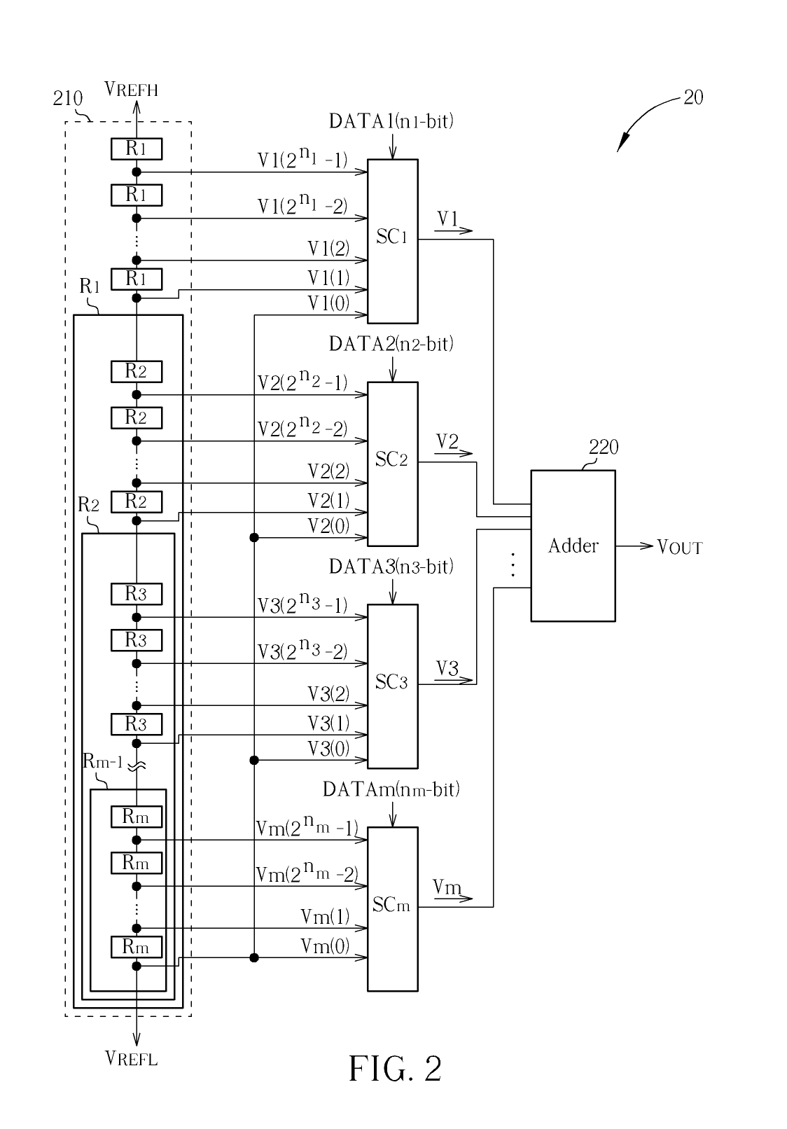

Reference is made to FIG. 2 for a diagram illustrating an N-bit DAC 20 according to the present invention. The DAC 20 receives an N-bit digital input data and provides a corresponding analog output voltage V_{OUT} with m-segmented conversion. In FIG. 2, the N-bit digital input data [D₀;D_{N-1}] is represented by DATA1-DATAm: DATA1 includes the n₁ most significant bits [D_{N-n1};D_{N-1}], DATA2 includes the next n₂ most significant bits [D_{N-n1-n2}; D_{N-n1-1}], . . . , and DATAm includes the nₘ least significant bits [D₀;Dₙ_{ₘ}₋₁], wherein n₁+n₂+ . . . +nₘ=N.

The DAC 20 includes a resistor string 210, m multiple-to-one selectors SC₁˜SCₘ, and an adder 220. The resistor string 210, coupled between a positive bias voltage V_{REFH} and a negative bias voltage V_{REFL}, can provide a plurality of reference voltages by voltage-dividing the voltage difference ΔV_{REF} (ΔV_{REF}=V_{REFH}−V_{REFL}). The resistor string 210, including 2^{N} voltage-dividing units R₁ coupled in series and each having identical resistance, thereby capable of providing 2ⁿ^{₁} reference voltages V1(0)˜V1(2ⁿ^{₁}−1) to the selector SC₁ by voltage-dividing the voltage difference ΔV_{REF}, wherein the values of the reference voltages V1(0)˜V1(2ⁿ^{₁}−1) sequentially increase from V_{REFL} with an increment of ΔV_{REF1} (ΔV_{REF1}=ΔV_{REF}/2ⁿ^{₁}). Among the 2^{N}^{₂} voltage-dividing units R₁, one voltage-dividing unit R₁ includes 2ⁿ^{₂} voltage-dividing units R₂ coupled in series and each having identical resistance, thereby capable of providing 2ⁿ^{₂} reference voltages V2(0)˜V2(2ⁿ^{₂}−1) to the selector SC₂ by voltage-dividing the voltage difference ΔV_{REF1}, wherein the values of the reference voltages V2(0)˜V2(2ⁿ^{₂}−1) sequentially increase from V_{REFL} with an increment of ΔV_{REF2}(ΔV_{REF2}=ΔV_{REF1}/2ⁿ^{₂}); . . . ; similarly, among the 2ⁿ^{ₘ₋₁} voltage-dividing units Rₘ₋₁, one voltage-dividing unit Rₘ₋₁ includes 2ⁿ^{ₘ} voltage-dividing units Rₘ coupled in series and each having identical resistance, thereby capable of providing 2ⁿ^{ₘ} reference voltages Vm(0)˜Vm(2ⁿ^{ₘ}−1) to the selector SCₘ by voltage-dividing the voltage difference ΔV_{REF(m-1)} (ΔV_{REF(}ₘ₋₁₎=ΔV_{REF(m-2)}/2ⁿ^{ₘ₋₁}), wherein the values of the reference voltages Vm(0)˜Vm(2ⁿ^{ₘ}−1) sequentially increase from V_{REFL} with an increment of ΔV_{REFm}(ΔV_{REFm}=ΔV_{REF(m-1)}/2ⁿ^{ₘ}).

In the present invention, the relationship between the resistances of the voltage-dividing units R₁-Rₘ is depicted as follows:

$${R}_{1} = {2}^{{n}_{2}} * {R}_{2} \\ {R}_{2} = {2}^{{n}_{3}} * {R}_{3} \\ … \\ {R}_{m - 1} = {2}^{{n}_{m}} * {R}_{m} \qquad ( 1 )$$

Therefore, the overall resistance R_{TOTAL} of the resistor string 210 can be represented as follows:

R_{TOTAL}=2ⁿ^{₁}*R₁=2⁽ⁿ^{₁}⁺ⁿ^{₂}⁾*R₂= . . . =2⁽ⁿ^{₁}⁺ⁿ^{₂}^{+ . . . +n}^{ₘ}⁾*Rₘ

The 2ⁿ^{₁}-to-1 selector SC₁ receives the 2ⁿ^{₁} reference voltages V1(0)˜V1(2ⁿ^{₁}−1) from the resistor string 210 and selects one of the received reference voltages as its output reference voltage V1 according to the digital data DATA1; the 2ⁿ^{₂}-to-1 selector SC₂ receives the 2ⁿ^{₂} reference voltages V2(0)˜V2(2ⁿ^{₂}−1) from the resistor string 210 and selects one of the received reference voltages as its output reference voltage V2 according to the digital data DATA2; . . . ; the s2ⁿ^{ₘ}-to-1 elector SCₘ receives the 2ⁿ^{ₘ} reference voltages Vm(0)˜Vm(2ⁿ^{ₘ}−1) from the resistor string 210 and selects one of the received reference voltages as its output reference voltage Vm according to the digital data DATAm. After summing the output reference voltages V1-Vm using the adder 220, the analog output voltage V_{OUT} corresponding to the original N-bit digital input data [D₀;D_{N-1}] can thus be acquired.

In other words, the present invention provides m-segmented voltage conversion. In the first segment of conversion, the 2^{N} voltage-dividing units R₁ coarsely divide the voltage difference ΔV_{REF} into 2ⁿ^{₁} identical voltages ΔV_{REF1} and thus output 2ⁿ^{₁} reference voltages V1(0)˜V1(2ⁿ^{₁}−1) respectively corresponding to the n₁ most significant bits of the N-bit digital input data. The selector SC₁ then selects one of the received reference voltages V1(0)˜V1(2ⁿ^{₁}−1) as the output reference voltage V1 according to the n₁-bit digital data DATA1; in the second segment of conversion, the 2ⁿ^{₂} voltage-dividing units R₂ further divide the voltage difference ΔV_{REF1} into 2ⁿ^{₂} identical voltages ΔV_{REF2} and thus output 2ⁿ^{₂} reference voltages V2(0)˜V2(2ⁿ^{₂}−1) respectively corresponding to the next n₂ most significant bits of the N-bit digital input data. The selector SC₂ then selects one of the received reference voltages V2(0)˜V2(2ⁿ^{₂}−1)as the output reference voltage V2 according to the n₂-bit digital data DATA2; . . . ; in the mth segment of conversion, the 2ⁿ^{ₘ} voltage-dividing units Rₘ further divide the voltage difference ΔV_{REF(m-1)} into 2ⁿ^{ₘ} identical voltages ΔV_{REFm} and thus output 2ⁿ^{ₘ} reference voltages Vm(0)˜Vm(2ⁿ^{ₘ}−1) respectively corresponding to the nₘ least significant bits of the N-bit digital input data. The selector SCₘ then selects one of the received reference voltages Vm(0)˜Vm(2ⁿ^{ₘ}−1)as the output reference voltage Vm according to the nₘ-bit digital data DATAm.

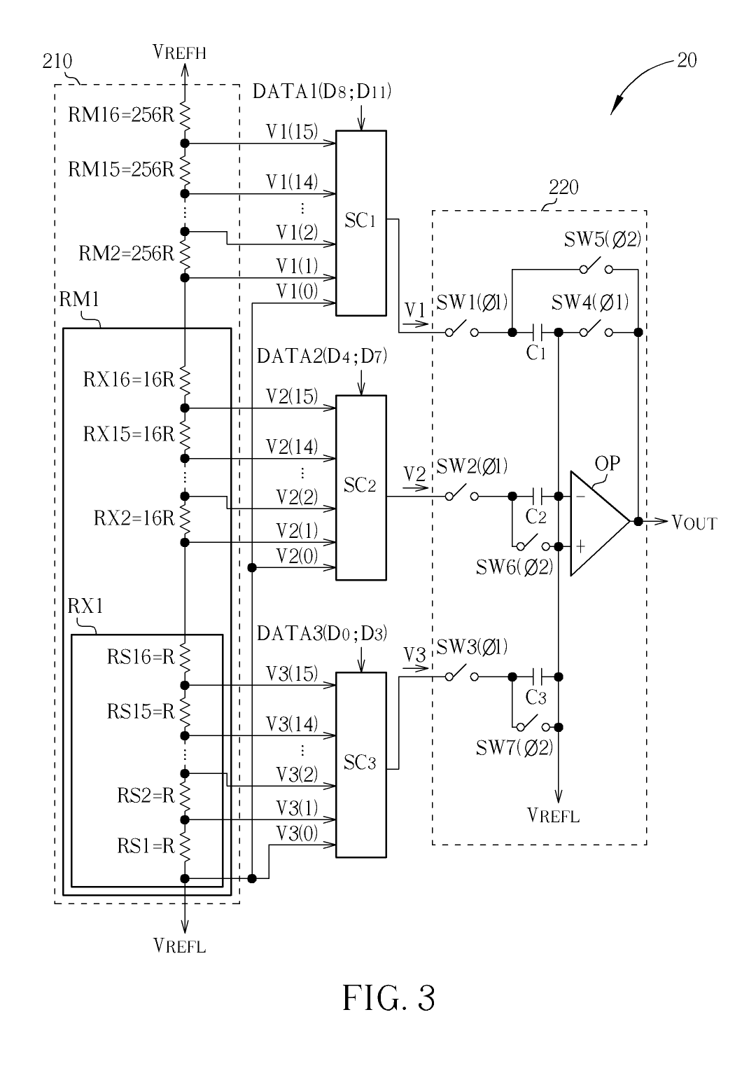

Reference is made to FIG. 3 for a diagram illustrating the DAC 20 according to an embodiment of the present invention. In this embodiment, the DAC 20 receives a 12-bit digital data [D₀;D₁₁], which is then divided into DATA1-DATA3: DATA1 corresponds to the 4 most significant bits [D₈;D₁₁], DATA2 corresponds to the 4 intermediate bits [D₄;D₇] and DATA3 corresponds to the 4 least significant bits [D₀;D₃]. After 3-segmented conversion using three multiple-to-one selectors SC₁-SC₃ and the adder 220, the corresponding analog output voltage V_{OUT} can thus be provided. In the embodiment depicted in FIG. 3, the resistor string 210, coupled between a positive bias voltage V_{REFH} and a negative bias voltage V_{REFL}, can perform the first segment of conversion using 16 voltage-dividing units RM1-RM16 coupled in series and each having resistance 256R, thereby capable of providing 16 reference voltages V1(0)˜V1(15) to the selector SC₁ by voltage-dividing the voltage difference ΔV_{REF}(ΔV_{REF}=V_{REFH}−V_{REFL}). Next, the second segment of conversion is performed using 16 voltage-dividing units RX1-RX16 coupled in series and each having resistance 64R, and 16 reference voltages V2(0)≠V2(15) can be provided to the selector SC₂ by voltage-dividing the voltage difference ΔV_{REF}/16. Next, the third segment of conversion is performed using 16 voltage-dividing units RS1-RS16 coupled in series and each having resistance R, and 16 reference voltages V3(0)˜V3(15) can be provided to the selector SC₃ by voltage-dividing the voltage difference ΔV_{REF}/256. The reference voltage V1-V3 outputted by the selectors SC₁-SC₃ to the adder 220 are respectively determined by DATA1-DATA3, as illustrated by the following equations:

$$\begin{matrix}V 1 = \frac{Δ {V}_{REF}}{{2}^{4}} DATA 1 + {V}_{REFL} & ( 2 ) \\ V 2 = \frac{Δ {V}_{REF}}{{2}^{4} {2}^{4}} DATA 2 + {V}_{REFL} & ( 3 ) \\ V 3 = \frac{Δ {V}_{REF}}{{2}^{4} {2}^{4} {2}^{4}} DATA 3 + {V}_{REFL} & ( 4 )\end{matrix}$$

In the embodiment illustrated in FIG. 3, the adder 220 includes an operational amplifier OP, capacitors C1-C3, and switches SW1-SW6. The switches SW1-SW4 operate according to a control signal Φ1, while the switches SW5-SW6 operate according to a control signal Φ2. The control signals Φ1 and Φ2 are periodical signals with non-overlapping phases: Q1 represents the amount of charge stored in the capacitors C1-C3 during the period of the control signal Φ1, while Q2 represents the amount of charge stored in the capacitors C1-C3 during the period of the control signal Φ2. Meanwhile, V_{OS} represents the offset voltage of the operational amplifier OP. Therefore, Q1 and Q2 can be represented as follows:

Q1=C1(V1−V_{REFL}−V_{OS})+C2(V2−V_{REFL}−V_{OS})+C3(V3−V_{REFL}−V_{OS}) Q2=C1(V_{OUT}−V_{REFL}−V_{OS})+C2(−V_{OS})+C3(−V_{OS})

According to charge conservation principle, Q1 is equal to Q2, and the output voltage V_{OUT} can be derived as follows:

V_{OUT}V1+(V2−V_{REFL})C2/C1+(V3−V_{REFL})C3/C1 (5)

Assuming C1=C2=C3 and according to equations (2)-(5), the following equation can be derived:

$$\begin{matrix}{V}_{OUT} = \frac{Δ {V}_{REF}}{{2}^{4}} DATA 1 + \frac{Δ {V}_{REF}}{{2}^{4} {2}^{4}} DATA 2 + \frac{Δ {V}_{REF}}{{2}^{4} {2}^{4} {2}^{4}} DATA 3 + {V}_{REFL} \\ = \frac{Δ {V}_{REF}}{{2}^{12}} ( {2}^{8} DATA 1 + {2}^{4} DATA 2 + DATA 3 ) + {V}_{REFL}\end{matrix}$$

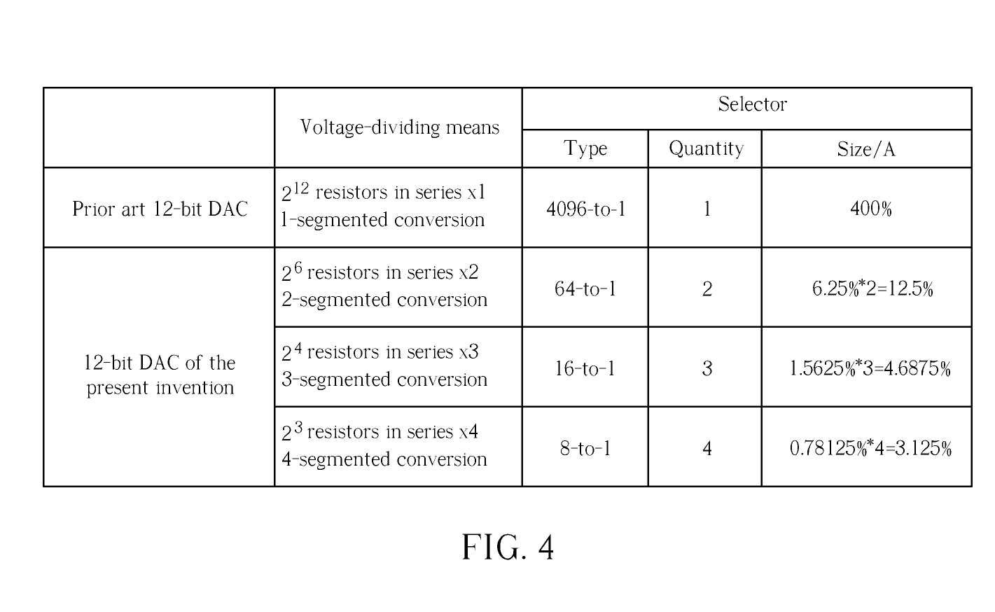

Reference is made to FIG. 4 for a table illustrating the difference between the prior art and the present invention. Assuming the size of a 10-bit DAC is A, 12-bit resolution is used for illustration in FIG. 4. When performing 1-segmented conversion using 2¹² resistors coupled in series and a 2¹²-to-1 selectors, the size of the prior art DAC is about 4A. The present invention can achieve size-reduction using multiple-segmented conversion: when performing 2-segmented conversion using two voltage-dividing units (each including 2⁶ resistors coupled in series) and one 2⁶-to-1 selector, the size of the DAC can be reduced to 12.5% A; when performing 3-segmented conversion using three voltage-dividing units (each including 2⁴ resistors coupled in series) and one 2⁴-to-1 selector, the size of the DAC can be reduced to 4.6875% A; when performing 4-segmented conversion using four voltage-dividing units (each including 2³ resistors coupled in series) and one 2³-to-1 selector, the size of the DAC can be reduced to 3.125% A.

In the present invention, each of the voltage-dividing units R₁-Rₘ can include a single resistor (as shown in FIG. 3), a plurality of resistors coupled in series, or resistors having other structure as long as equation (1) is satisfied. Meanwhile, the present invention can adopt various types of adders. The resistor string 210 and the adder 220 depicted in FIG. 3 are merely for illustrative purpose, and do not limit the scope of the present invention.

The present invention provides an analog output voltage corresponding to an N-bit digital input data with m-segmented conversion. Since n₁-nₘ bits of the N-bit digital input data are respectively converted in each segment (n₁+n₂+ . . . +nₘ=N), only a small-size selector is required. The present invention can reduce the size of the DAC and increase design flexibility.

Those skilled in the art will readily observe that numerous modifications and alterations of the device and method may be made while retaining the teachings of the invention.

What is claimed is:

1. A digital-to-analog converter (DAC) which receives an N-bit digital input data and provides a corresponding analog voltage with multi-segmented conversion, the DAC comprising:
a resistor string including:
2^{A} first voltage-dividing units coupled in series for providing 2^{A} reference voltages respectively corresponding to A most significant bits of the N-bit digital input data, a first voltage-dividing unit among the 2^{A} first voltage-dividing units comprising:
2^{B} second voltage-dividing units coupled in series for providing 2^{B} reference voltages respectively corresponding to B most significant bits of the N-bit digital input data after the A most significant bits of the N-bit digital input data, a second voltage-dividing unit among the 2^{B} second voltage-dividing units comprising:
2^{C} third voltage-dividing units coupled in series for providing 2^{C} reference voltages respectively corresponding to C most significant bits of the N-bit digital input data after the (A+B) most significant bits of the N-bit digital input data, wherein N, A, B and C are positive integers and a sum of A, B and C does not exceed N;
a first multiple-to-one selector for receiving the 2^{A} reference voltages outputted by the first voltage-dividing unit and outputting one of the received 2^{A} reference voltages according to an A-bit digital signal;
a second multiple-to-one selector for receiving the 2^{B} reference voltages outputted by the second voltage-dividing unit and outputting one of the received 2^{B} reference voltages according to a B-bit digital signal;
a third multiple-to-one selector for receiving the 2^{C} reference voltages outputted by the third voltage-dividing unit and outputting one of the received 2^{C} reference voltages according to a C-bit digital signal; and
an adder for generating the analog voltage by summing the reference voltages outputted by the first, second and third multiple-to-one selectors.

2. The DAC of claim 1 wherein each first voltage-dividing unit has a substantially identical resistance, each second voltage-dividing unit has a substantially identical resistance, and each third voltage-dividing unit has a substantially identical resistance.

3. The DAC of claim 1 wherein a resistance of each first voltage-dividing unit is substantially equal to an equivalent resistance of the 2^{B} voltage-dividing units.

4. The DAC of claim 1 wherein a resistance of each second voltage-dividing unit is substantially equal to an equivalent resistance of the 2^{C} voltage-dividing units.

5. The DAC of claim 1 wherein the C most significant bits after the (A+B) most significant bits of the N-bit digital input data are C least significant bits of the N-bit digital input data.

6. The DAC of claim 1 wherein A, B and C have an identical value.

7. The DAC of claim 1 wherein a third voltage-dividing unit among the 2^{C} third voltage-dividing units comprises:
2^{D} fourth voltage-dividing units coupled in series for providing 2^{D} reference voltages respectively corresponding to D least significant bits of the N-bit digital input data.

8. The DAC of claim 7 wherein A, B, C and D have an identical value.

9. The DAC of claim 7 wherein a sum of A, B, C and D is equal to N.

10. The DAC of claim 1 wherein the A-bit digital data includes the A most significant bits of the N-bit digital input data, the B-bit digital data includes the B most significant bits of the N-bit digital input data after the A most significant bits of the N-bit digital input data, and the C-bit digital data includes the C most significant bits of the N-bit digital input data after the (A+B) most significant bits of the N-bit digital input data.

11. The DAC of claim 1 wherein the resistor string is coupled between a first bias voltage and a second bias voltage whose level is lower than that of the first bias voltage.

12. The DAC of claim 11 wherein the 2^{A} first voltage-dividing units coupled in series provide the 2^{A} reference voltages by equally dividing a first voltage difference established between the first and second bias voltages into 2^{A} second voltage differences, the 2^{B} second voltage-dividing units coupled in series provide the 2^{B} reference voltages by equally dividing the second voltage difference into 2^{B} third voltage differences, and the 2^{C} third voltage-dividing units coupled in series provide the 2^{C} reference voltages by equally dividing the third voltage difference into 2^{C} fourth voltage differences.

13. The DAC of claim 1 wherein a sum of A, B and C is equal to N.
